(19) United States
(12) Patent Application Publication
(10) Pub. No.: US 2026/0013123 A1
(43) Pub. Date: Jan. 8, 2026

(54) NON-VOLATILE MEMORY WITH COUNTER-DOPED IMPLANT AND METHOD OF MANUFACTURING SAME

(71) Applicant: STMICROELECTRONICS INTERNATIONAL N.V., Geneva (CH)

(72) Inventor: Francois TAILLIET, Fuveau (FR)

(21) Appl. No.: 18/761,821

(22) Filed: Jul. 2, 2024

(51) Int. Cl. H10B 41/70; H10B 41/35

(52) U.S. Cl. CPC H10B 41/70; H10B 41/35

(57) ABSTRACT

In accordance with various embodiments of the present disclosure, a memory cell of an electrically erasable and programmable nonvolatile memory device is provided. In some embodiments, the memory cell comprises a source region, a drain region, a channel region, a control gate, a floating gate, and a counter-doped implant. The floating gate includes a protruding portion that is separated from the channel region by a first region of an insulating layer that is thinner than a second region of the insulating layer that separates one or more remaining portions of the floating gate from the channel region. The implant is positioned in the channel region under the first region of the insulating layer. The implant is either less P-doped than the channel region or N-doped lightly enough that the implant inverts to P-doped when a voltage is applied during an erase operation.

### BACKGROUND

Electrically erasable and programmable memory (EEPROM) devices comprise a plurality of non-volatile memory cells or bitcells. Fowler-Nordheim (“FN”) bitcells are one type of EEPROM bitcell. Examples of such FN bitcells are described in commonly-owned U.S. Pat. No. 10,049,741 to Tailliet, issued Aug. 14, 2018, and titled NON-VOLATILE MEMORY WITH FLOATING GATE HAVING PROTRUDING PORTION; U.S. Pat. No. 10,727,239 to Tailliet, issued Jul. 28, 2020 and titled COMPACT EEPROM MEMORY CELL WITH A GATE DIELECTRIC LAYER HAVING TWO DIFFERENT THICKNESSES; and U.S. Pat. No. 11,696,438 to Tailliet, issued Jul. 4, 2023, and titled COMPACT EEPROM MEMORY CELL WITH A GATE DIELECTRIC LAYER HAVING TWO DIFFERENT THICKNESSES, the contents of all of which are incorporated by reference herein in their entirety.

### FIELD OF THE INVENTION

Example embodiments of the present disclosure relate generally to non-volatile memories and, in particular, to electrically erasable and programmable non-volatile memories (EEPROM).

As shown in FIG. 1, such an FN bitcell 100 includes a word line transistor or access transistor 105 and a sense transistor 110 that comprises a control gate 115 and a floating gate 120. Each access transistor 105 is coupled, via its source region, to a corresponding source line 125 and each sense transistor 110 is coupled, via its drain region, to a corresponding bit line 130.

In FIG. 1, MN1 refers to the channel portion of the access transistor 105. The sense transistor 110 has two different oxide thicknesses. In FIG. 1, MN2 refers to the channel portion of the sense transistor covered by a relatively thin tunnel oxide (typically about 7.6 nanometers (nm) thick), while MN3 refers to the channel portion of the sense transistor covered by a relative thick high voltage oxide (typically about 21 nm thick). MN2 may be termed an injection transistor.

The substrate of such a bitcell is P doped. Because the P doping region in the channel is the same for MN2 and MN3, and because the gate oxide thickness is about three times less for MN2 than MN3, the threshold voltage of MN2 is initially much less than the threshold voltage of MN3. In this regard, the conduction of the sense transistor is determined by MN3 (i.e., when MN3 turns on, MN2 is already conductive). So, the threshold of (MN2+MN3) is the threshold of MN3.

Because of the high voltages applied during the write cycles, charges are trapped within the thinner tunnel oxide. The degradation of the injection transistor caused by these trapped charges increase the voltage threshold of MN2 over time. Because MN3 has a thick oxide layer, there is little to no degradation in MN3. As the voltage threshold of MN2 increases over time, the conduction of the sense transistor is progressively determined by MN2 instead of MN3, which is undesirable.

This is illustrated in FIG. 4, in which the threshold voltage of MN2 (dashed line) and the threshold voltage of MN3 (dotted line) are illustrated over a very large number (e.g., millions) of erase and program cycles (shown on a logarithmic scale). The threshold voltage of MN3 stays flat over time, while the threshold voltage of MN2 increases over time due to the trapped charges. The dot-dash line represents the conduction voltage of the sense transistor, which is determined by threshold voltage of MN3 until threshold voltage of MN2 has increased such that threshold voltage of MN2 exceeds the threshold voltage of MN3 (indicated by the vertical dashed line in FIG. 4). At that point, the conduction voltage of the sense transistor is determined by threshold voltage of MN2.

Applicant has identified many technical challenges and difficulties associated with FN type EEPROM bitcells. Through applied effort, ingenuity, and innovation, Applicant has solved problems related FN type EEPROM bitcells by developing solutions embodied in the present disclosure, which are described in detail below.

### BRIEF SUMMARY

Various embodiments described herein related to electrically erasable and programmable nonvolatile memory devices, and methods for manufacturing electrically erasable and programmable nonvolatile memory devices.

In accordance with various embodiments of the present disclosure, a memory cell of an electrically erasable and programmable nonvolatile memory device is provided. In some embodiments, the memory cell comprises a source region disposed in a semiconductor body, a drain region disposed in the semiconductor body, a channel region disposed in the semiconductor body, a control gate, a floating gate disposed between the semiconductor body and the control gate, and a counter-doped implant. The floating gate includes a protruding portion that is located over the channel region between the source and drain regions and spaced therefrom. The protruding portion is separated from the channel region by a first region of an insulating layer that is thinner than a second region of the insulating layer that separates one or more remaining portions of the floating gate from the channel region. The implant is positioned in the channel region under the first region of the insulating layer. The implant is either less P-doped than the channel region or N-doped lightly enough that the implant inverts to P-doped when a voltage is applied during an erase operation.

In some embodiments, the implant is positioned only under the first region of the insulating layer and does not extend under the second region of the insulating layer.

In some embodiments, the implant is counter-doped with arsenic or phosphorous.

In accordance with various embodiments of the present disclosure, a memory cell of an electrically erasable and programmable nonvolatile memory device is provided. In some embodiments, the memory cell comprises a source region disposed in a semiconductor body, a drain region disposed in the semiconductor body, a channel region disposed in the semiconductor body, a control gate, a floating gate disposed between the semiconductor body and the control gate, and a counter-doped implant. The floating gate includes a protruding portion that is located over the channel region between the source and drain regions and spaced therefrom. The protruding portion is separated from the channel region by a first region of an insulating layer that is thinner than a second region of the insulating layer that separates one or more remaining portions of the floating gate from the channel region. The counter-doped implant is positioned in the channel region under the first region of the insulating layer. The implant causes a reduction in a threshold voltage of a portion of the channel region beneath the implant.

In accordance with various embodiments of the present disclosure, a method of manufacturing an electrically erasable and programmable nonvolatile memory device comprising a memory cell is provided. In some embodiments, the method comprises forming a first dielectric layer over a surface of a semiconductor substrate, the first dielectric layer having a first thickness; removing a portion of the first dielectric layer to form an opening; forming a second dielectric layer over the first dielectric layer and the opening, the second dielectric layer having a second thickness less than the first thickness; accelerating a plurality of ions toward the second dielectric layer at an energy level selected such that some of the plurality of ions penetrate the second dielectric layer in an area of the opening to form a counter-doped implant in the semiconductor substrate aligned with the opening; forming a floating gate layer over the second dielectric layer; forming a control gate dielectric layer over the floating gate layer; forming a control gate layer over the control gate dielectric layer; and removing portions of the floating gate layer, the control gate dielectric layer, and the control gate layer to form a floating gate and a control gate.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a simplified schematic of a bitcell of a prior art electrically erasable and programmable nonvolatile memory device;

FIG. 2 illustrates an example architecture of an example bitcell of an example electrically erasable and programmable nonvolatile memory device, in accordance with some embodiments of the present disclosure;

FIG. 3 illustrates an example architecture of an example bitcell of an example electrically erasable and programmable nonvolatile memory device, in accordance with some alternative embodiments of the present disclosure;

FIG. 4 illustrates voltage threshold curves of a prior art bitcell of an electrically erasable and programmable nonvolatile memory device; and

FIG. 5 illustrates voltage threshold curves of a bitcell of an example electrically erasable and programmable nonvolatile memory device, in accordance with some embodiments of the present disclosure.

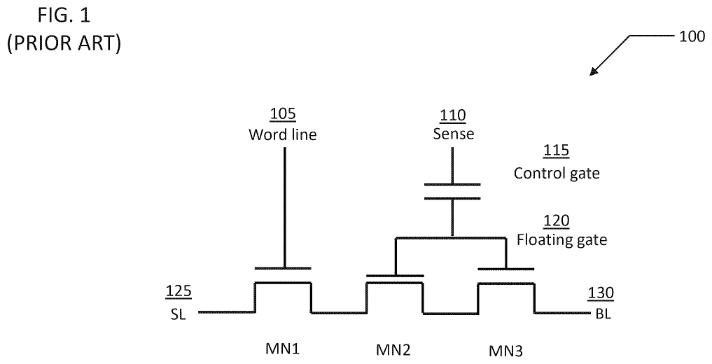

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing electrically erasable and programmable nonvolatile memory (EEPROM) devices in which, for each bitcell, a counter-doped implant is positioned in the channel region of the substrate to lower the threshold voltage of the portion of the channel region beneath the implant (i.e., MN2). By lowering the threshold voltage of MN2, various embodiments of the present disclosure shift the MN2 threshold voltage curve downward. Thus, even though the voltage threshold of MN2 still increases over time due to trapped charges, the lower MN2 threshold voltage of various embodiments of the present disclosure ensures that many more cycles are possible before the MN2 threshold voltage has increased to the point where the conduction of the sense transistor is determined by MN2 instead of MN3.

In various embodiments, the implant is positioned under the thin region of the insulating layer (e.g., the oxide layer). In various embodiments, the implant is either less P-doped than the channel region or N-doped lightly enough that the implant inverts to P-doped when a voltage is applied during an erase operation. That is, in various embodiments, the implant remains or becomes P doped when a high negative voltage is applied during an erase operation.

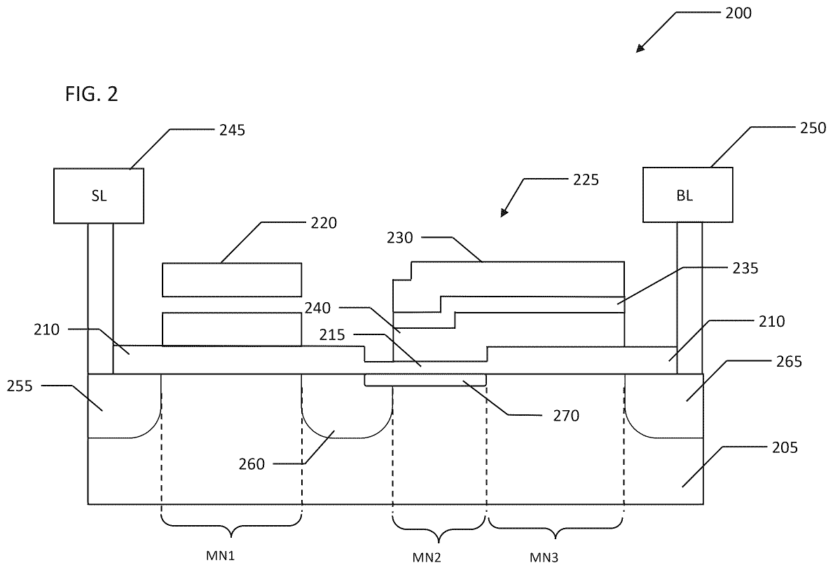

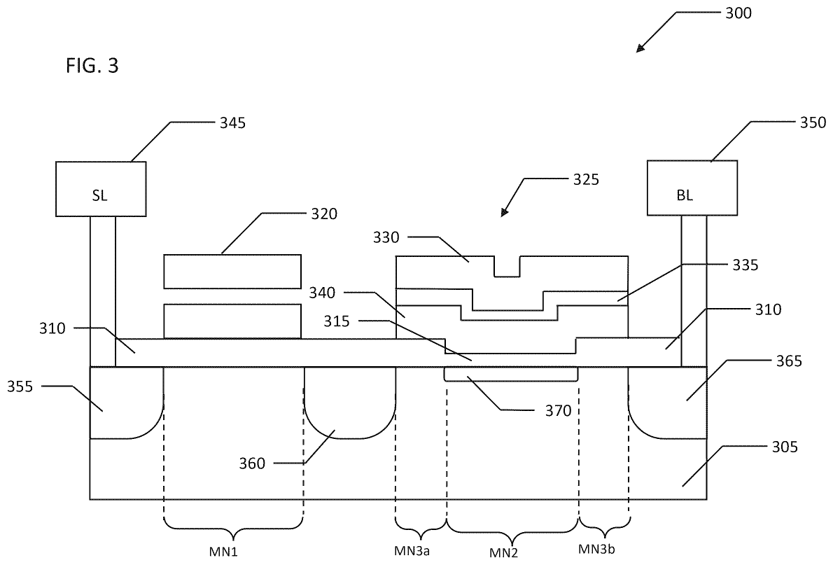

FIG. 2 illustrates an example architecture of an example bitcell of an example electrically erasable and programmable nonvolatile memory device, in accordance with some embodiments of the present disclosure. In various embodiments, an example EEPROM device would comprise a plurality of the bitcells illustrated in FIG. 2 and/or FIG. 3. For example, an example EEPROM device may comprise between a few hundred and a few million of such bitcells.

As seen in FIG. 2, an example bitcell 200 comprises a substrate 205, an insulating or dielectric layer having relatively thicker portions 210 (typically about 21 nm thick) and a relatively thinner portion 215 (typically about 7.6 nm thick), a access transistor 220 on the thicker portion 210 of the dielectric layer, a sense transistor 225 partially on the thicker portion 210 of the dielectric layer and partially on the thinner portion 215 of the dielectric layer, a source line 245, and a bit line 250. Formed within the substrate 205 is a source region 255 for the access transistor 220, a drain region 265 for the sense transistor 225, and a combined source/drain region 260 that is the drain for the access transistor 220 and the source for the sense transistor 225. In the illustrated embodiment, the sense transistor 225 comprises a control gate 230 and a floating gate 240 separated by a gate dielectric layer 235. The floating gate 240 comprises a portion that protrudes downward into the space created above the thinner portion 215 of the dielectric layer.

In FIG. 2, MN1 refers to the channel portion of the access transistor 220, MN2 refers to the channel portion of the sense transistor 225 beneath the relatively thin portion 215 of the dielectric layer, and MN3 refers to the channel portion of the sense transistor 225 beneath the relatively thicker portion 210 of the dielectric layer.

In various embodiments, a counter-doped implant 270 is formed in the substrate 205 beneath the thinner portion 215 of the dielectric layer. In various embodiments, the implant 270 is either less P-doped than the substrate 205 or is N-doped lightly enough that the implant inverts to P-doped when a voltage is applied during an erase operation.

In various embodiments, as illustrated, the implant 270 is positioned only under the thinner portion 215 of the dielectric layer and does not extend under the thicker portion 210 of the dielectric layer. In some embodiments, for example, the implant is counter-doped with arsenic or phosphorous. In various embodiments, the counter-doped implant is shallow. For example, the depth of such a counter-doped implant typically does not exceed the depth of the source and drain implanted regions (e.g., elements 255, 260, 265 in FIG. 2 and elements 355, 360, 365 in FIG. 3). In various embodiments, the counter-doped implant is created using low dose, low energy doping atoms.

In various embodiments, the counter-doped implant 270 lowers the threshold voltage of MN2, so that even after significant increases due to gate stress, the voltage threshold of MN2 is still less than the voltage threshold of MN3 and the conduction of the sense transistor continues to be controlled by MN3 (whose characteristics do not shift) for a longer time. In various embodiments, the doping of the counter-doped implant is selected to decrease the voltage threshold of MN2 by about 1 volt (V).

In various embodiments, the counter-doped implant does not change the standard operation of the standard erase/program/read cycles of the EEPROM device. In various embodiments, in the erase phase, a control gate voltage of about −15V and a floating gate voltage of about −10V will accumulate the P bulk in MN3, the implant (which is either less P doped than the rest of the channel or lightly N doped) will remain P or invert from N to P (the inversion voltage is about −1V and there is about −10V on the floating gate), such that the erase operation is unchanged from the standard erase operation since the injection is on a P area. In various embodiments, in the program phase, a control gate voltage of about +15V and a floating gate voltage of about +10V will invert the P bulk in MN3 like before, the channel of MN2 will be accumulated (and more N), with a channel created all along the sense transistor, with MN3 and MN2 in series, in an ON state since the injection is on a N area. In various embodiments, in the read phase, the (MN2+MN3) conduction is controlled by MN3, even if MN2 is degraded (due to the lowered voltage threshold of MN2).

An EEPROM bitcell, such as the bitcell 200 of FIG. 2, can be created using any suitable semiconductor manufacturing methods. In one example embodiment, an EEPROM bitcell is created via at least the following steps/operations (for simplicity, the steps/operations for creating some of the structures of such an example bitcell are omitted): forming a semiconductor substrate; forming a first dielectric layer over a surface of the semiconductor substrate, the first dielectric layer having a first thickness; removing a portion of the first dielectric layer to form an opening; forming a second dielectric layer over the first dielectric layer and the opening, the second dielectric layer having a second thickness less than the first thickness; forming a counter-doped implant by accelerating a plurality of ions toward the second dielectric layer at an energy level selected such that some of the ions penetrate the second dielectric layer in the area of the opening to form a counter-doped implant in the semiconductor substrate aligned with the opening; forming a floating gate layer over the second dielectric layer; forming a control gate dielectric layer over the floating gate layer; forming a control gate layer over the control gate dielectric layer; and removing portions of the floating gate layer, the control gate dielectric layer, and the control gate layer to form a floating gate and a control gate.

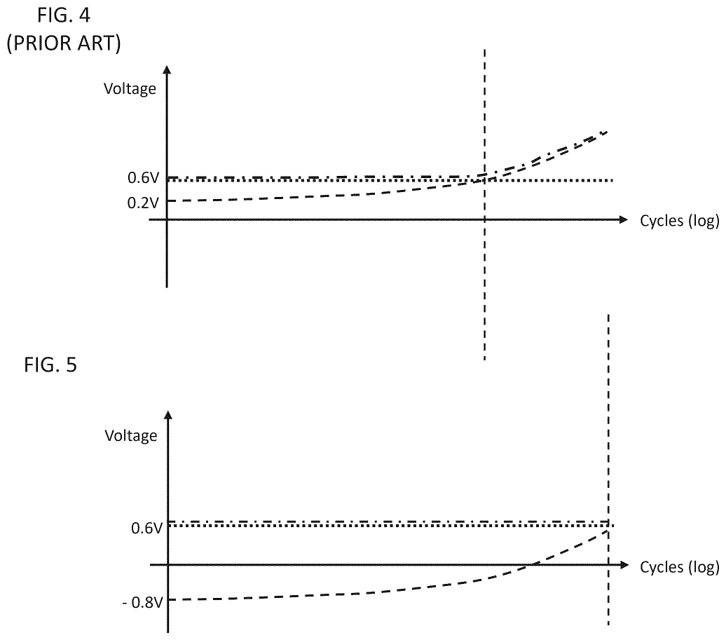

In various embodiments, such a counter-doped implant lowers the threshold voltage of the portion of the channel region beneath the implant (i.e., MN2). By lowering the threshold voltage of MN2, various embodiments of the present disclosure shift the entire MN2 threshold voltage curve downward. This ensures that many more cycles are possible before the MN2 threshold voltage has increased to the point where the conduction of the sense transistor is determined by MN2 instead of MN3. This is illustrated in FIG. 5, in which the threshold voltage of MN2 (dashed line) and the threshold voltage of MN3 (dotted line) are illustrated over a very large number (e.g., millions) of erase and program cycles (shown on a logarithmic scale). The threshold voltage of MN3 stays flat over time, while the threshold voltage of MN2 increases over time due to the trapped charges. However, by lowering the threshold voltage of MN2 by (in the illustrated embodiment) about 1V (from 0.2V to −0.8V, as compared to FIG. 4), the entire curve of the threshold voltage of MN2 is shifted down and the point at which the threshold voltage of MN2 has increased such that threshold voltage of MN2 exceeds the threshold voltage of MN3 (indicated by the vertical dashed line in FIG. 5) is shifted rightward (as compared to FIG. 4), thereby enabling many more cycles of the EEPROM device.

FIG. 3 illustrates an example architecture of an example bitcell of an example electrically erasable and programmable nonvolatile memory device, in accordance with some alternative embodiments of the present disclosure. As seen in FIG. 3, an example bitcell 300 comprises a substrate 305, an insulating or dielectric layer having relatively thicker portions 310 (typically about 21 nm thick) and a relatively thinner portion 315 (typically about 7.6 nm thick), a access transistor 320 on the thicker portion 310 of the dielectric layer, a sense transistor 325 partially on the thicker portion 310 of the dielectric layer and partially on the thinner portion 315 of the dielectric layer, a source line 345, and a bit line 350. Formed within the substrate 305 is a source region 355 for the access transistor 320, a drain region 365 for the sense transistor 325, and a combined region 360 that is the drain for the access transistor 320 and the source for the sense transistor 325. In the illustrated embodiment, the sense transistor 325 comprises a control gate 330 and a floating gate 340 separated by a gate dielectric layer 335. The floating gate 340 comprises a portion that protrudes downward into the space created above the thinner portion 315 of the dielectric layer.

In FIG. 3, MN1 refers to the channel portion of the access transistor 320, MN2 refers to the channel portion of the sense transistor 325 beneath the relatively thin portion 315 of the dielectric layer, and MN3a, MN3b refer to the channel portions of the sense transistor 325 beneath the relatively thicker portion 310 of the dielectric layer (which, in this embodiment, surround MN2).

In various embodiments, a counter-doped implant 370 is formed in the substrate 305 beneath the thinner portion 315 of the dielectric layer. In various embodiments, the implant 370 is either less P-doped than the substrate 305 or is N-doped lightly enough that the implant inverts to P-doped when a voltage is applied during an erase operation. In various embodiments, as illustrated, the implant 370 is positioned only under the thinner portion 315 of the dielectric layer and does not extend under the thicker portion 310 of the dielectric layer.

Any suitable materials known in semiconductor manufacturing may be used to manufacture the example bitcells of FIGS. 2 and 3. For example, in some embodiments, the substrate may comprise monocrystalline silicon, the dielectric layer on the substrate may comprise an oxide such as silicon dioxide applied in two layers (as described below), the gates of the access transistor and of the sense transistor may comprise polysilicon. In various embodiments, the monocrystalline silicon of the substrate is often epitaxial, not bulk. That is, the top layer is the substrate is the epitaxial layer which is a few microns thick and contains all of the components, while the bottom layer is the bulk which is typically a few hundreds of microns thick, has a low resistivity, and contains nothing. The two polysilicon gates of the access transistor and the sense transistor may be separated by an oxide type sandwich of SIO2/SI3N4/SIO2.In the illustrated example, the access transistor has a structure of two stacked gates like the sense transistor for process realization concerns, but in some embodiments the access transistor could use only the top polysilicon gate. In other embodiments, the access transistor could be of the trench type in which the gate goes deep in the substrate. In some embodiments, when the access transistor uses two stacked gates, the two gates (which make the word line) are typically short-circuited and are at the same potential. The short-circuit is made somewhere along the word line, outside the bitcell (i.e., not in the plane of the bitcell cross-section). The source and/or drains of the sense or access transistor are typically made of a same arsenic implantation.

In various embodiments, a counter-doped implant as described herein performs differently than a capacitive implant (often termed a “capa implant”) of an FN type bitcell Such capa implants are described, for example, in U.S. Pat. No. 10,049,741, 10,727,239, and 11,696,438, which are incorporated by reference above. Such capa implants are heavily N-doped to prevent inversion during programming. The heavy N-doping of such capa implants would prevent proper erase operation of bitcells of embodiments of the present disclosure.

In various embodiments, a counter-doped implant as described herein increases significantly the endurance of FN type EEPROM bitcells by correcting the asymmetrical window closure during endurance tests. This correction is done by lowering the threshold of the transistor corresponding to the injection area, which has a thin gate oxide and is subjected to gate stress degradation. Lowering the threshold postpones the point at which this transistor controls the conduction of the sense transistor due to its degradation.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of EEPROM having FN type bitcells. As another example, the appended claims may cover EEPROM bitcells using hot carriers for at least one operation among the erase or program operations.

Within the appended claims, unless the specific term “means for” or “step for” is used within a given claim, it is not intended that the claim be interpreted under 35 U.S.C. 112, paragraph 6.

What is claimed is:

1. An electrically erasable and programmable nonvolatile memory device comprising a memory cell, the memory cell comprising:
a source region disposed in a semiconductor body;
a drain region disposed in the semiconductor body;
a channel region disposed in the semiconductor body;
a control gate;
a floating gate disposed between the semiconductor body and the control gate, wherein the floating gate includes a protruding portion that is located over the channel region between the source and drain regions and spaced therefrom, the protruding portion being separated from the channel region by a first region of an insulating layer that is thinner than a second region of the insulating layer that separates one or more remaining portions of the floating gate from the channel region; and
a counter-doped implant positioned in the channel region under the first region of the insulating layer, wherein the implant is either less P-doped than the channel region or N-doped lightly enough that the implant inverts to P-doped when a voltage is applied during an erase operation.

2. The device of claim 1, wherein the implant is positioned only under the first region of the insulating layer and does not extend under the second region of the insulating layer.

3. The device of claim 1, wherein the implant is counter-doped with arsenic or phosphorous.

4. An electrically erasable and programmable nonvolatile memory device comprising a memory cell, the memory cell comprising:
a source region disposed in a semiconductor body;
a drain region disposed in the semiconductor body;
a channel region disposed in the semiconductor body;
a control gate;
a floating gate disposed between the semiconductor body and the control gate, wherein the floating gate includes a protruding portion that is located over the channel region between the source and drain regions and spaced therefrom, the protruding portion being separated from the channel region by a first region of an insulating layer that is thinner than a second region of the insulating layer that separates one or more remaining portions of the floating gate from the channel region; and
a counter-doped implant positioned in the channel region under the first region of the insulating layer, wherein the implant causes a reduction in a threshold voltage of a portion of the channel region beneath the implant.

5. The device of claim 4, wherein the implant is either less P-doped than the channel region or N-doped lightly enough that the implant inverts to P-doped when a voltage is applied during an erase operation.

6. The device of claim 4, wherein the implant is positioned only under the first region of the insulating layer and does not extend under the second region of the insulating layer.

7. The device of claim 4, wherein the implant is counter-doped with arsenic or phosphorous.

8. A method of manufacturing an electrically erasable and programmable nonvolatile memory device comprising a memory cell, the method comprising:
forming a first dielectric layer over a surface of a semiconductor substrate, the first dielectric layer having a first thickness;
removing a portion of the first dielectric layer to form an opening;
forming a second dielectric layer over the first dielectric layer and the opening, the second dielectric layer having a second thickness less than the first thickness;
accelerating a plurality of ions toward the second dielectric layer at an energy level selected such that some of the plurality of ions penetrate the second dielectric layer in an area of the opening to form a counter-doped implant in the semiconductor substrate aligned with the opening;
forming a floating gate layer over the second dielectric layer;
forming a control gate dielectric layer over the floating gate layer;
forming a control gate layer over the control gate dielectric layer; and
removing portions of the floating gate layer, the control gate dielectric layer, and the control gate layer to form a floating gate and a control gate.

9. The method of claim 8, wherein the plurality of ions comprises a plurality of arsenic ions or a plurality of phosphorous ions.

10. The method of claim 8, wherein the implant is counter-doped to a level sufficient to cause a reduction in a threshold voltage of a portion of a channel region beneath the implant.

11. The method of claim 8, wherein the implant is either less P-doped than the semiconductor substrate or N-doped lightly enough that the implant inverts to P-doped when a voltage is applied during an erase operation.
